(19) United States
(12) Patent Application Publication
(10) Pub. No.: US 2010/0052072 A1
(43) Pub. Date: Mar. 4, 2010

(54) DUAL GATE STRUCTURE ON A SAME CHIP FOR HIGH-K METAL GATE TECHNOLOGY

(75) Inventors: Chii-Horng Li, Jhu-Bei City (TW); Po-Nien Chen, Miaoli City (TW); Chung-Hau Fei, Hsinchu City (TW); Chien-Liang Chen, Hsinchu City (TW); Wen-Chih Yang, Huatan Township (TW); Harry Chuang, Hsin Chu City (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/368,044

(22) Filed: Feb. 9, 2009

Related U.S. Application Data
(60) Provisional application No. 61/092,576, filed on Aug. 28, 2008.

(51) Int. Cl. H01L 27/06; H01L 21/02

(52) U.S. Cl. 257/380; 438/382; 257/E27.016; 257/E21.004

(57) ABSTRACT

A semiconductor device and method for fabricating a semiconductor device is disclosed. The method includes providing semiconductor substrate having a first region and a second region, forming a high-k dielectric layer over the semiconductor substrate, forming a capping layer over the high-k dielectric layer, forming a metal layer over the capping layer, removing the metal layer and capping layer in the second region, forming a polysilicon layer over the metal layer in the first region and over the high-k dielectric layer in the second region, and forming an active device with the metal layer in the first region and forming a passive device without the metal layer in the second region.

### PRIORITY DATA

This application claims priority to Provisional Application Ser. No. 61/092,576 filed on Aug. 28, 2008, entitled “Dual Gate Structure On A Same Chip For High-K Metal Gate Technology”, the entire disclosure of which is incorporated herein by reference.

### BACKGROUND

The course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices. CMOS devices have typically been formed with a gate oxide and polysilicon gate electrode. There has been a desire to replace the gate oxide and polysilicon gate electrode with a high-k gate dielectric and metal gate electrode to improve device performance as feature sizes continue to decrease. However, problems arise when integrating a high-k/metal gate feature in a CMOS process flow due to various factors such as incompatibility of materials, complex processes, and thermal budgets.

For example, polysilicon resistors have been widely used in conventional integrated circuit design, including for RC oscillators, current limitation resistance, ESD protect, RF post drivers, on-chip termination, impedance matching, etc. Also, polysilicon electronic fuses (eFuses) have also been widely used in conventional memory integrated circuit design. However, integrating high-k metal gate technology with these types of devices has been challenging. In some situations, the polysilicon resistors and polysilicon eFuses may exhibit a lower than desirable resistivitiy following fabrication, and thus these devices may be ineffective for its intended function.

Accordingly, what is needed are semiconductor devices that address the above stated issues, and methods for making such semiconductor devices.

### SUMMARY

One of the broader forms of an embodiment of the invention involves a method for fabricating a semiconductor device. The method includes providing semiconductor substrate having a first region and a second region; forming a high-k dielectric layer over the semiconductor substrate; forming a capping layer over the high-k dielectric layer; forming a metal layer over the capping layer; removing the metal layer and the capping layer overlying the second region; forming a polysilicon layer over the metal layer overlying the first region and over the high-k dielectric layer overlying the second region; and forming an active device with the metal layer in the first region and forming a passive device without the metal layer in the second region.

Another one of the broader forms of an embodiment of the invention involves a semiconductor device. The semiconductor device includes a semiconductor substrate having a first region and a second region; a transistor formed in the first region, the transistor having a gate stack that includes a high-k dielectric disposed over the substrate, a capping layer disposed over the high-k dielectric, and a metal gate disposed over the capping layer; and a passive device formed in the second region, the passive device including the high-k dielectric and a polysilicon layer disposed over the high-k dielectric, the passive device not including the metal gate.

Yet another one of the broader forms of an embodiment of the invention involves a method for fabricating a semiconductor device. The method includes providing semiconductor device having a first region and a second region; forming a high-k dielectric layer over the semiconductor substrate; forming a capping layer over the high-k dielectric layer; forming a metal layer over the capping layer; removing the metal layer in the second region; forming a polysilicon layer over the metal layer in the first region and over the capping layer in the second region; and forming an active device with the metal layer in the first region and forming a passive device without the metal layer in the second region.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for only illustration purposes. In fact, the dimensions of the various features may be arbitrarily increased or reduced for clarity of discussion.

FIG. 1 is a flowchart of a method for forming a semiconductor device having a dual gate structure according to various aspects of the present disclosure;

FIGS. 2A to 2C are cross-sectional views of a semiconductor at various stages of fabrication according to the method of FIG. 1;

FIG. 3 is a flowchart of an alternative method for forming a semiconductor device having a dual gate structure according to various aspects of the present disclosure;

FIGS. 4A to 4C are cross-sectional views of a semiconductor device at various stages of fabrication according to the method of FIG. 3; and

FIG. 5 is a top view of an eFuse device that may be implemented in the semiconductor devices of FIGS. 2 and 4.

### DETAILED DESCRIPTION

It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

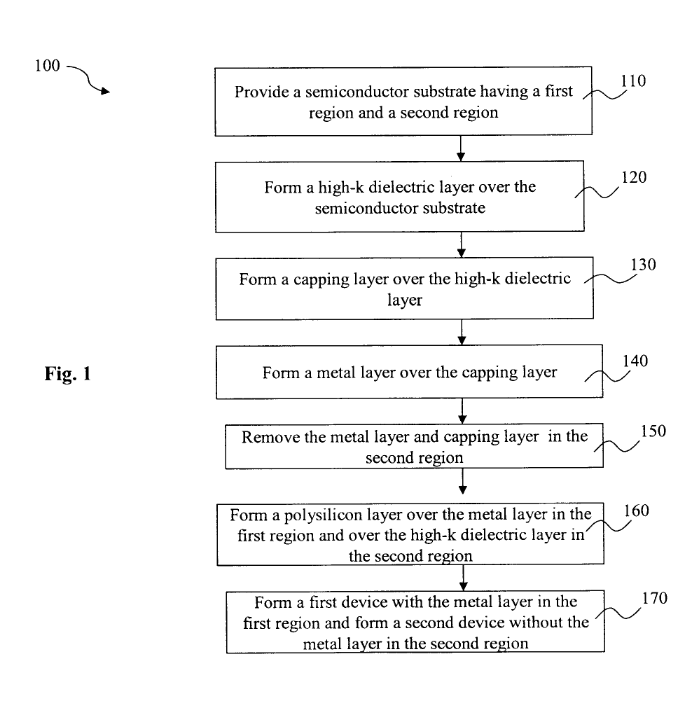

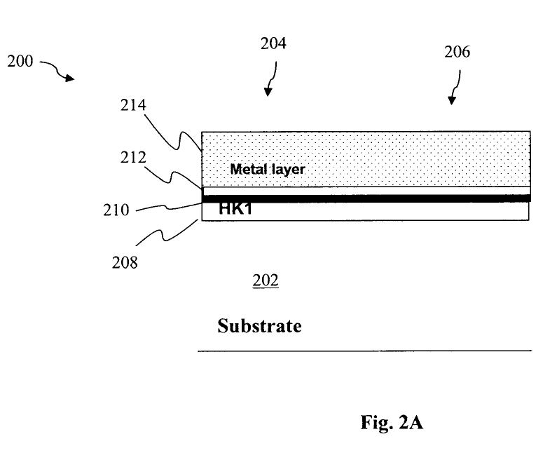

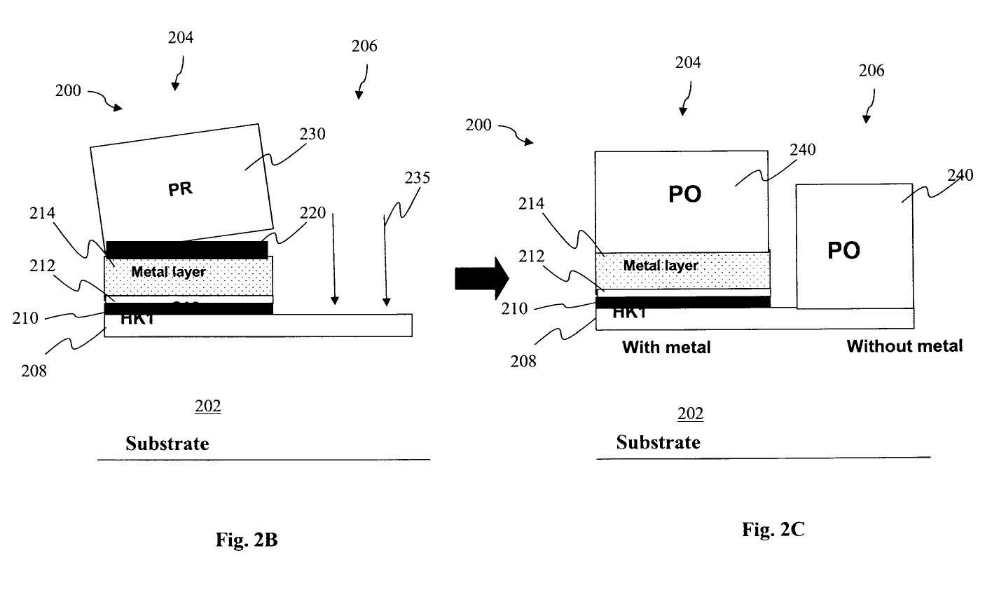

Referring to FIG. 1, illustrated is a method 100 for fabricating a semiconductor device including a device with a metal structure and a device without a metal structure according to various aspects of the present disclosure. Referring also to FIGS. 2A to 2C, illustrated are cross-sectional views of a semiconductor device 200 at various stages of fabrication according to the method 100 of FIG. 1. It is understood that part of the semiconductor device 200 may be fabricated with normal CMOS technology process flow, and thus some processes are briefly described herein. Also, FIGS. 2A to 2C are simplified for a better understanding of the inventive concepts of the present disclosure.

The method 100 begins with block 110 in which a semiconductor substrate having a first region and a second region may be provided. In FIG. 2A, the semiconductor device 200 may include a semiconductor substrate 202 such as a silicon substrate. The substrate 202 may alternatively include silicon germanium, gallium arsenic, or other suitable semiconductor materials. The substrate 202 may further include other features such as various doped regions such as p-wells or n-wells, a buried layer, and/or an epitaxy layer. Furthermore, the substrate 202 may be a semiconductor on insulator such as silicon on insulator (SOI). In other embodiments, the semiconductor substrate 202 may include a doped epi layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

The semiconductor device 200 may further include an isolation structure (not shown) formed in the substrate 202 for isolating active regions in the substrate 202. The isolation structure may be formed of silicon oxide, silicon nitride, silicon oxynitride, fluoride-doped silicate (FSG), and/or a low k dielectric material. The isolation structure may utilize isolation technology, such as local oxidation of silicon (LOCOS) or shallow trench isolation (STI), to define and electrically isolate the various active regions in the substrate.

The semiconductor device 200 may include a region 204 for forming an active microelectronic device in various embodiments, such as P-channel field effect transistors (PFETs), N-channel field effect transistors (NFETs), metal-oxide semiconductor field effect transistors (MOSFETs), complementary metal-oxide semiconductor transistors (CMOSs), bipolar transistors, high voltage transistors, high frequency transistors, other suitable devices, and/or combinations thereof. The semiconductor device 200 may further include a region 206 for forming a variety of passive microelectronic devices in various embodiments, such as resistors, capacitors, inductors, fuses, other suitable components, and/or combinations thereof.

The method 100 continues with block 120 in which a high-k dielectric layer may be formed over the semiconductor substrate. The semiconductor device 200 may further include a gate dielectric layer 208 including an interfacial layer/high-k dielectric layer formed over the substrate 202. The interfacial layer may include a silicon oxide (e.g., thermal oxide or chemical oxide by ALD) layer having a thickness ranging from about 5 to about 10 angstrom (Å). The interfacial layer may be formed on the substrate 202. The high-k dielectric layer may be formed on the interfacial layer by atomic layer deposition (ALD), chemical vapor deposition (CVD), or other suitable technique. The high-k dielectric layer may include a thickness ranging from about 10 to about 40 angstrom (Å). The high-k dielectric layer may include hafnium oxide (HfO₂). Alternatively, the high-k dielectric layer may optionally include other high-k dielectrics such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), and combinations thereof.

The method 100 continues with block 130 in which a capping layer may be formed over the high-k dielectric layer. The semiconductor device 200 may further include one or more capping layers for tuning a work function of the metal gate for properly performing as an NMOS transistor device and a PMOS transistor device, respectively. For example, a capping layer 210 may be formed over the gate dielectric layer 208 by CVD, ALD, or other suitable deposition process. Also, another capping layer 212 may be formed over the capping layer 210 by CVD, ALD, or other suitable deposition process. The capping layers 210, 212 may include lanthanum oxide, LaSiO, manganese oxide, aluminum oxide, or other suitable dielectric materials.

The method 100 continues with block 140 in which a metal layer may be formed over the capping layer. The semiconductor device 200 may further include a metal layer 214 formed over the gate dielectric layer 204. The metal layer 214 may be any metal material suitable for forming a metal gate or portion thereof, including work function layers, liner layers, interface layers, seed layers, adhesion layers, barrier layers, etc. The metal layer 214 may include a thickness ranging from about 10 to about 500 angstrom (Å). The metal layer 214 may be formed by various deposition techniques such as CVD, physical vapor deposition (PVD or sputtering), plating, or other suitable technique. The metal layer 214 may include a P-type work function metal (P-metal) or an N-type work function metal (N-metal) or combination thereof. The metal layer 214 may include TiN, TiAlN, Al, TaN, TaSiN, ZrSi₂, MoSi₂, TaSi₂, NiSi₂, WN, W, TaC, TaCN, combinations thereof, or other suitable metal material.

The method 100 continues with block 150 the metal layer and the capping layer in the first region may be removed. In FIG. 2B, a buffer layer 220 may optionally be formed on the metal layer 214 to reduce the risk of peeling of a subsequent photoresist layer used for patterning. In other words, the buffer layer 220 may provide a better adhesive surface for the photoresist as compared to the metal layer 214. The buffer layer 220 may include silicon nitride, silicon oxynitride, lanthanum oxide, or other suitable dielectric material. A photoresist layer 230 may be formed over the buffer layer 220 and may be patterned to cover the region 204 and expose the region 206. The photoresist layer 230 may be patterned by a photolithography process. The photolithography process may include spin coating, soft-baking, exposure, post-baking, developing, rinsing, drying, and other suitable process. Alternatively, the patterning may be performed by immersion lithography, electron beam lithography, or other suitable process.

An dry or wet etch process may be performed to pattern the buffer layer 220 to cover the region 204, and the patterned buffer layer 220 may be used as a mask to perform an etch process 235 on the metal layer 214 and capping layers 210, 212 in the region 206. The etch process 235 may have high selectivity such that the etch process may stop at the high-k dielectric layer 208. The photoresist layer 230 may be removed by a stripping or other suitable process. The buffer layer 220 may be removed by a wet etch process or other suitable process.

The method 100 continues with block 160 in which a polysilicon layer may be formed over the metal layer in the first region and the high-k dielectric layer in the second region. In FIG. 2C, the semiconductor device 200 may further include a polysilicon or poly layer 240 formed on the metal layer 214 in the region 204 and on the high-k dielectric layer 208 in the region 206. The poly layer 240 may be formed by deposition or other suitable process. The poly layer 240 may have a thickness ranging from 200 to about 1000 angstrom (Å).

The method 100 continues with block 170 in which a first device with the metal layer may be formed in the first region, and a second device without the metal layer may be formed in the second region. As previously noted, an active device may be formed in the region 204 with the high-dielectric layer 208, capping layers 210, 212, metal layer 214, and poly layer 240, and a passive device may be formed in the region 206 with the high-k dielectric layer 208 and poly layer 240. For example, a transistor such as an nFET or pFET device may be formed in the region 204 and a polysilicon resistor may be formed in the region 206 using a CMOS process flow. Accordingly, a gate etching or patterning process may be performed to form a gate structure with the metal layer 214, high-k dielectric 208, and poly layer 240 in the region 204 and a resistive structure with the high-k dielectric 208 and poly layer 240 but without the metal layer in the region 206. It is understood that various other features may be formed such as lightly doped drain (LDD) regions, sidewalls spacers (gate spacers), source/drain (S/D) regions, silicide features, contact etch stop layer, contacts/vias, interlayer dielectric (ILD) layers, metal layers, and so forth.

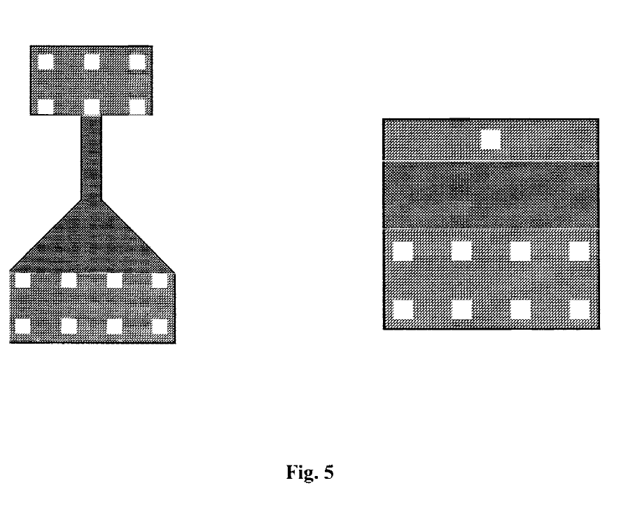

In some embodiments, the polysilicon layer 240 of the resistor may be doped (by ion implantation) to achieve a desired resistance value. Additionally, the resistor may include various shapes such as a line, dog bone, rectangle, other suitable shapes, and/or combinations thereof. Further, the resistor may include a silicide feature formed during a salicidation process. Alternatively, the resistor may include a resist protection oxide (RPO) instead of the silicide feature. The RPO may be a dielectric layer, such as an oxide layer, a nitride layer, an oxynitride layer, other suitable layers, and/or combinations thereof. It should be noted that the resistive structure formed in the region 206 does not have the metal layer, and thus the resistivity may not be reduced such that it can no longer be used for its intended purpose. In other embodiments, a polysilicon eFuse with a high-k dielectric 208 and poly layer 240 may also be formed in the region 206. The process that forms the polysilicon eFUSE is similar to the process that forms the resistor. For example, during gate etching or patterning, the eFuse may be formed by patterning the poly layer 240 an high-k dielectric 208 in the region 206 to form a portion for an anode, a portion for a cathode, and a portion for a fuse link as illustrated in some examples of FIG. 5.

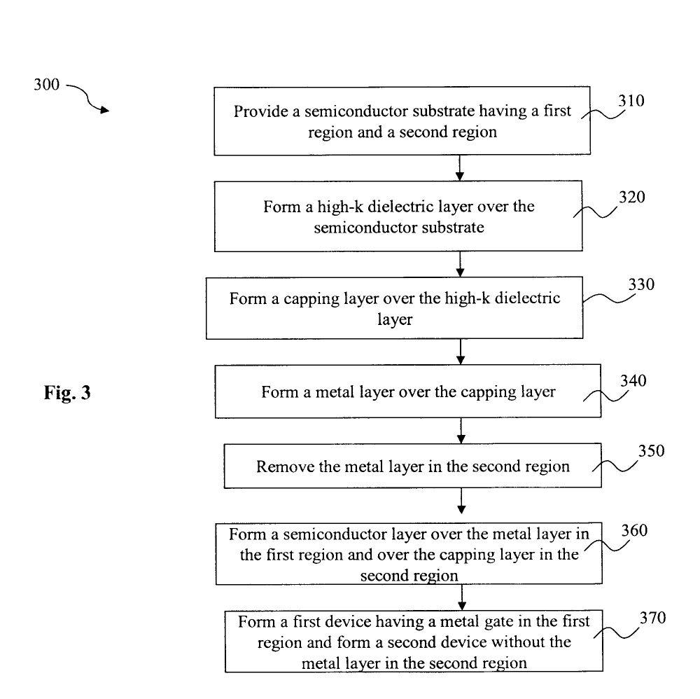

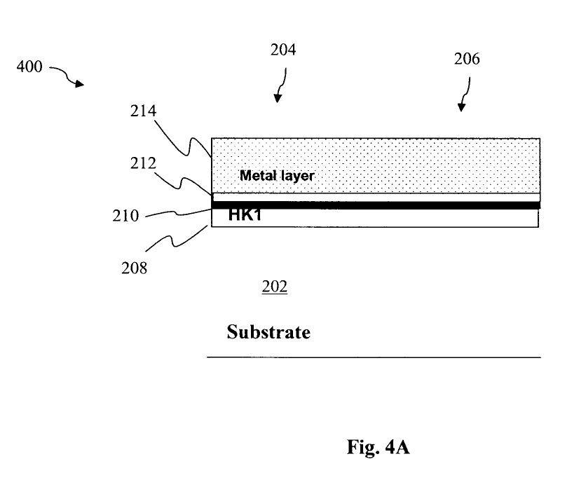

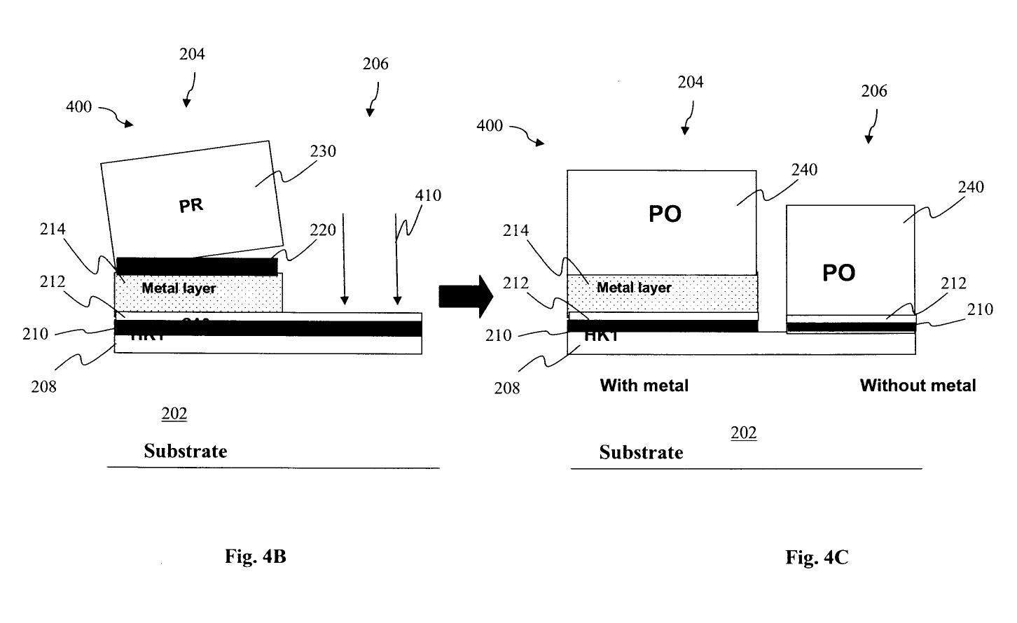

Referring to FIG. 3, illustrated is an alternative method 300 for fabricating a semiconductor device including a device with a metal structure and a device without a metal structure according to various aspects of the present disclosure. Referring also to FIGS. 4A to 4C, illustrated are cross-sectional views of a semiconductor device 400 at various stages of fabrication according to the method 300 of FIG. 3. It is understood that part of the semiconductor device 400 may be fabricated with normal CMOS technology processes, and thus some processes are briefly described herein. Also, FIGS. 4A to 4C are simplified for a better understanding of the inventive concepts of the present disclosure. The semiconductor device 400 is similar to the semiconductor device 200 of FIG. 2 except for the differences disclosed below. Similar features in FIGS. 2 and 4 are numbered the same for the sake of simplicity and clarity.

The method 300 begins with block 310 in which a semiconductor substrate having a first region and a second region may be provided. In FIG. 4A, the semiconductor device 200 may include a semiconductor substrate 202 such as a silicon substrate. The substrate 202 may alternatively include silicon germanium, gallium arsenic, or other suitable semiconductor materials. The substrate 202 may further include other features such as various doped regions such as p-wells or n-wells, a buried layer, and/or an epitaxy layer. Furthermore, the substrate 202 may be a semiconductor on insulator such as silicon on insulator (SOI). In other embodiments, the semiconductor substrate 202 may include a doped epi layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

The semiconductor device 200 may further include an isolation structure (not shown) formed in the substrate 202 for isolating active regions in the substrate 202. The isolation structure may be formed of silicon oxide, silicon nitride, silicon oxynitride, fluoride-doped silicate (FSG), and/or a low k dielectric material. The isolation structure may utilize isolation technology, such as local oxidation of silicon (LOCOS) or shallow trench isolation (STI), to define and electrically isolate the various active regions in the substrate.

The semiconductor device 200 may include a region 204 for forming an active microelectronic device in various embodiments, such as P-channel field effect transistors (PFETs), N-channel field effect transistors (NFETs), metal-oxide semiconductor field effect transistors (MOSFETs), complementary metal-oxide semiconductor transistors (CMOSs), bipolar transistors, high voltage transistors, high frequency transistors, other suitable devices, and/or combinations thereof. The semiconductor device 200 may further include a region 206 for forming a variety of passive microelectronic devices in various embodiments, such as resistors, capacitors, inductors, fuses, other suitable components, and/or combinations thereof.

The method 300 continues with block 320 in which a high-k dielectric layer may be formed over the semiconductor substrate. The semiconductor device 200 may further include a gate dielectric layer 208 including an interfacial layer/high-k dielectric layer formed over the substrate 202. The interfacial layer may include a silicon oxide (e.g., thermal oxide or chemical oxide by ALD) layer having a thickness ranging from about 5 to about 10 angstrom (Å). The interfacial layer may be formed on the substrate 202. The high-k dielectric layer may be formed on the interfacial layer by atomic layer deposition (ALD), chemical vapor deposition (CVD), or other suitable technique. The high-k dielectric layer may include a thickness ranging from about 10 to about 40 angstrom (Å). The high-k dielectric layer may include hafnium oxide (HfO2). Alternatively, the high-k dielectric layer may optionally include other high-k dielectrics such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), and combinations thereof.

The method 300 continues with block 330 in which a capping layer may be formed over the high-k dielectric layer. The semiconductor device 200 may further include one or more capping layers for tuning a work function of the metal gate for properly performing as an NMOS transistor device and a PMOS transistor device, respectively. For example, a capping layer 210 may be formed over the gate dielectric layer 208 by CVD, ALD, or other suitable deposition process. Also, another capping layer 212 may be formed over the capping layer 210 by CVD, ALD, or other suitable deposition process. The capping layers 210, 212 may include lanthanum oxide, LaSiO, manganese oxide, aluminum oxide, or other suitable dielectric materials.

The method 300 continues with block 340 in which a metal layer may be formed over the capping layer. The semiconductor device 200 may further include a metal layer 214 formed over the gate dielectric layer 208. The metal layer 214 may be any metal material suitable for forming a metal gate or portion thereof, including work function layers, liner layers, interface layers, seed layers, adhesion layers, barrier layers, etc. The metal layer 214 may include a thickness ranging from about 10 to about 500 angstrom (Å). The metal layer 214 may be formed by various deposition techniques such as CVD, physical vapor deposition (PVD or sputtering), plating, or other suitable technique. The metal layer 214 may include a P-type work function metal (P-metal) or an N-type work function metal (N-metal) or combination thereof. The metal layer 214 may include TiN, TiAlN, Al, TaN, TaSiN, ZrSi₂, MoSi₂, TaSi₂, NiSi₂, WN, W, TaC, TaCN, combinations thereof, or other suitable metal material.

The method 300 continues with block 350 the metal layer in the first region may be removed. In FIG. 4B, a buffer layer 220 may optionally be formed on the metal layer 214 to reduce the risk of peeling of a subsequent photoresist layer used for patterning. In other words, the buffer layer 220 may provide a better adhesive surface for the photoresist as compared to the metal layer 214. The buffer layer 220 may include silicon nitride, silicon oxynitride, lanthanum oxide or other suitable dielectric material. A photoresist layer 230 may be formed over the buffer layer 220 and may be patterned to cover the region 204 and expose the region 206. The photoresist layer 230 may be patterned by a photolithography process. The photolithography process may include spin coating, soft-baking, exposure, post-baking, developing, rinsing, drying, and other suitable process. Alternatively, the patterning may be performed by immersion lithography, electron beam lithography, or other suitable process.

An dry or wet etch process may be performed to pattern the buffer layer 220 to cover the region 204, and the patterned buffer layer 220 may be used as a mask to perform an etch process 410 on the metal layer 214 in the region 206. The etch process 410 may have high selectivity such that the etch process may stop at the capping layer 212. The photoresist layer 230 may be removed by a stripping or other suitable process. The buffer layer 220 may be removed by a wet etch process or other suitable process.

The method 300 continues with block 360 in which a polysilicon layer may be formed over the metal layer in the first region and the capping layer in the second region. In FIG. 4C, the semiconductor device 200 may further include a polysilicon or poly layer 240 formed on the metal layer 214 in the region 204 and on the capping layer 212 in the region 206. The poly layer 240 may be formed by deposition or other suitable process. The poly layer 240 may have a thickness ranging from 400 to about 800 angstrom (Å).

The method 300 continues with block 370 in which a first device with the metal layer may be formed in the first region, and a second device without the metal layer may be formed in the second region. As previously noted, an active device may be formed in the region 204 with the high-dielectric layer 208, capping layers 210, 212, metal layer 214, and poly layer 240, and a passive device may be formed in the region 206 with the high-k dielectric layer 208, capping layers 210, 212, and poly layer 240. For example, a transistor such as an nFET or pFET device may be formed in the region 204 and a polysilicon resistor may be formed in the region 206 using CMOS process flow. A gate etching or patterning process may be performed to form a gate structure with the metal layer 214 in the region 204 and a resistive structure without the metal layer in the region 206. It is understood that various other features may be formed such as lightly doped drain (LDD) regions, sidewalls spacers (gate spacers), source/drain (S/D) regions, silicide features, contact etch stop layer, contacts/vias, interlayer dielectric (ILD) layers, metal layers, and so forth. It should be noted that the capping layers 210, 212 are formed of a dielectric material (not a conductive material), and thus will not effect the resistivity of the device in the region 206.

In some embodiments, the polysilicon layer 240 of the resistor may be doped (by ion implantation) to achieve a desired resistance value. Additionally, the resistor may include various shapes such as a line, dog bone, rectangle, other suitable shapes, and/or combinations thereof. Further, the resistor may include a silicide feature formed during a salicidation process. Alternatively, the resistor may include a resist protection oxide (RPO) instead of the silicide feature. The RPO may be a dielectric layer, such as an oxide layer, a nitride layer, an oxy-nitride layer, other suitable layers, and/or combinations thereof. It should be noted that the resistive structure formed in the region 206 does not have the metal layer, and thus the resistivity may not be reduced such that it can no longer be used for its intended purpose. In other embodiments, a polysilicon eFUSE may also be formed in the region 206. The process that forms the polysilicon eFUSE is similar to the process that forms the resistor. For example, during gate etching or patterning, the eFuse may be formed by patterning the poly layer 240 and high-k dielectric 208 in the region 206 to form a portion for an anode, a portion for a cathode, and a portion for a fuse link as illustrated in some examples of FIG. 5.

Thus, the present disclosure provides methods and devices that may be implemented in applications that incorporate high-k metal gate technology with non-metal technologies such as a polysilicon resistor or polysilicon eFUSE or other passive devices. It is understood that the gate structure and the resistive structure may be formed simultaneously, utilizing the same processing steps and processing materials; the gate structure and the resistive structure may be formed independently of one another, utilizing varying processing steps and processing materials; or the gate structure and the resistive structure may be formed using a combination of simultaneous and independent processing steps and processing materials. Also, it should be noted that the gate structure of the transistor in the region 204 and the resistive structure in the region 206 may lie in substantially different planes (due to the removal of the metal layer and/or capping layers in region 206). Accordingly, a replacement poly gate process (gate last process) may also be implemented in the disclosed embodiments to remove the dummy poly from the gate structure of the transistor in the region 204 without damaging or removing the poly from the resistive structure in the region 206. Thus, the resistivity of the structure is not adversely affected in the gate last process or in a hybrid process that includes a gate first flow and gate last flow.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
providing semiconductor substrate having a first region and a second region;
forming a high-k dielectric layer over the semiconductor substrate;
forming a capping layer over the high-k dielectric layer;
forming a metal layer over the capping layer;
removing the metal layer and the capping layer overlying the second region;
forming a polysilicon layer over the metal layer overlying the first region and over the high-k dielectric layer overlying the second region; and
forming an active device with the metal layer in the first region and forming a passive device without the metal layer in the second region.

2. The method of claim 1, wherein the active device includes one of a nMOSFET and pMOSFET.

3. The method of claim 2, wherein the active device includes a gate stack including the high-k dielectric layer, the capping layer, and the metal layer.

4. The method of claim 3, wherein the gate stack further includes the polysilicon layer.

5. The method of claim 1, wherein the passive device includes one of a polyresistor and a poly eFuse.

6. The method of claim 5, further comprising doping the polysilicon layer to achieve a desired resistivity for the passive device.

7. A semiconductor device, comprising:
a semiconductor substrate having a first region and a second region;
a transistor formed in the first region, the transistor having a gate stack that includes a high-k dielectric disposed over the substrate, a capping layer disposed over the high-k dielectric, and a metal gate disposed over the capping layer; and
a passive device formed in the second region, the passive device including the high-k dielectric and a polysilicon layer disposed over the high-k dielectric, the passive device not including the metal gate.

8. The semiconductor device of claim 7, wherein the transistor includes one of an nFET and pFET.

9. The semiconductor device of claim 7, wherein the passive device includes one of a polyresistor and a poly eFuse.

10. The semiconductor device of claim 9, wherein the polysilicon layer is doped to achieve a desired resistivity.

11. The semiconductor device of claim 7, wherein a top surface of the gate stack of the transistor and a top surface of the polysilicon layer of the passive device are non-planar.

12. The semiconductor device of claim 7, wherein the passive device further includes the capping layer disposed over the high-k dielectric;
wherein the polysilicon layer is disposed on the capping layer.

13. A method for fabricating a semiconductor device, comprising:
providing semiconductor device having a first region and a second region;
forming a high-k dielectric layer over the semiconductor substrate;
forming a capping layer over the high-k dielectric layer;
forming a metal layer over the capping layer;
removing the metal layer in the second region;
forming a polysilicon layer over the metal layer in the first region and over the capping layer in the second region; and
forming an active device with the metal layer in the first region and forming a passive device without the metal layer in the second region.

14. The method of claim 13, wherein the active device includes one of a nFET and pFET.

15. The method of claim 14, wherein the active device includes a gate stack including the high-k dielectric, the capping layer, and the metal layer.

16. The method of claim 15, wherein the gate stack further includes the polysilicon layer formed over the metal layer.

17. The method of claim 13, wherein the passive device includes one of a polyresistor and a poly eFuse.

18. The method of claim 17, further comprising doping the polysilicon layer to achieve a desired resistivity for the passive device.

19. The method of claim 13, further comprising forming an interfacial layer on the semiconductor substrate;
wherein the high-k dielectric layer is formed on the interfacial layer.

20. The method of claim 13, wherein removing the metal layer in the second region includes:
forming a buffer layer over the metal layer;
forming a photoresist layer over the buffer layer;
patterning the photoresist layer to protect the buffer layer in the first region;
etching the buffer layer using the patterned photoresist layer as a mask; and
etching the metal layer in the second region using the patterned buffer layer as a mask.
